(19) United States
(12) Patent Application Publication
(10) Pub. No.: US 2002/0038905 A1
(43) Pub. Date: Apr. 4, 2002

(54) Semiconductor device provided in thin package and method for manufacturing the same

(75) Inventor: Yoshiaki Sugizaki, Yokohama-shi (JP)

Correspondence Address: Finnegan, Henderson, Farabow, Garrett & Dunner, L.L.P., 1300 I Street, N.W., Washington, DC, 20005-3315, US

(73) Assignee: KABUSHIKI KAISHA TOSHIBA

(21) Appl. No.: 09/961,304

(22) Filed: Sep. 25, 2001

(30) Foreign Application Priority Data
Sep. 29, 2000 (JP) 2000-300435

(51) Int. Cl. H01L 23/02

(52) U.S. Cl. 257/678

(57) ABSTRACT

A semiconductor device includes a wiring board, semiconductor chip, internal connection terminals, insulating resin layer, reinforcing member, and supporting plate. The semiconductor chip is arranged with the circuit forming surface of semiconductor elements facing the wiring board. The internal connection terminals are disposed between the wiring board and the semiconductor chip to electrically connect the wiring board and semiconductor chip to each other. The insulating resin layer is formed between the wiring board and the semiconductor chip to surround the internal connection terminals. The reinforcing member is provided at least on a semiconductor chip mounting surface of the wiring board. The supporting plate is provided on the reinforcing member.

### CROSS-REFERENCE TO RELATED APPLICATIONS

This application is based upon and claims the benefit of priority from the prior Japanese Patent Application No. 2000-300435, filed Sep. 29, 2000, the entire contents of which are incorporated herein by reference.

### BACKGROUND OF THE INVENTION

1. Field of the Invention

This invention relates to a semiconductor device and a method for manufacturing the same and more particularly to a semiconductor device provided in a thin package and a method for manufacturing the same.

2. Description of the Related Art

Conventionally, as a technique for making a semiconductor chip thin, a BSG (Back Side Grinding) technique for grinding the rear surface of a semiconductor wafer by use of a grindstone having resin embedded with diamond powder has been used. However, with the above technique, since a large number of scratches are made on the rear surface of the semiconductor wafer, there occurs a problem that the resistance against breakage of the obtained semiconductor chip is extremely lowered.

In order to solve the above problem, a technique for reducing the number of scratches and maintaining a high resistance against breakage by chemically etching the rear surface of the semiconductor wafer has been developed. However, even by using the above method, there occurs a problem that the semiconductor wafer after etching is warped and cracked if an attempt is made to reduce the thickness of the semiconductor chip to 100 μm or less.

In order to solve the above problems, a technique for simultaneously attaining a reduction in the thickness and separation of the semiconductor chip by forming a groove according to the external form of the semiconductor chip on the main surface (circuit forming surface) side of the semiconductor chip before grinding the rear surface thereof and then grinding the semiconductor chip from the rear surface side until the groove is reached is proposed in Jpn. Pat. Appln. KOKAI Publication No. H11-40520, for example.

FIGS. 1A to 1E are views schematically showing the steps for illustrating a manufacturing method of a semiconductor device disclosed in Jpn. Pat. Appln. KOKAI Publication No. H11-40520. FIG. 1A shows a dicing groove forming step, FIG. 1B shows a holding tape re-affixing step, FIG. 1C shows a BSG step, FIG. 1D shows a holding tape re-affixing step, and FIG. 1E shows a pickup step.

That is, first, after a holding tape 3 is affixed to the rear surface opposite to a circuit forming surface of a wafer 1 on which semiconductor elements have been formed, a dicing groove 2 is formed according to the external forms of the semiconductor chips on the circuit forming surface side (FIG. 1A). The dicing groove 2 has a depth less than the thickness of the wafer 1 and larger than the thickness of a finally obtained semiconductor chip. Next, the holding tape 3 of the semiconductor wafer 1 is removed from the rear surface opposite to the circuit forming surface and a holding tape 4 is affixed to the circuit forming surface (FIG. 1B) and then the rear surface of the semiconductor wafer 1 is ground by use of the BSG technique (FIG. 1C). After this, the holding tape 4 is removed from the circuit forming surface and a holding tape 6 is affixed to the rear surface (FIG. 1D), and then a semiconductor chip 15 is picked up from the holding tape 6 by use of pickup needles 16 (FIG. 1E).

By use of the above technique, since a separate devices (semiconductor chips 15) are obtained when the wafer 1 is made thin, the occurrence of cracks due to warps can be greatly suppressed and a semiconductor chip with a thickness of 100 μm or less can be formed at high manufacturing yield.

However, the above technique is an improvement over the conventional technique, but since the semiconductor chip whose thickness is reduced to 100 μm or less does not always have a sufficiently high strength, and the warp thereof is relatively large, it is required to perform extremely delicate operations by those skilled in the art in order to prevent the manufacturing yield from being lowered owing to damage occurring in later steps.

### BRIEF SUMMARY OF THE INVENTION

According to an aspect of the present invention, there is provided a semiconductor device comprising a wiring board; a semiconductor chip arranged with a circuit forming surface thereof facing the wiring board; internal connection terminals disposed between the wiring board and the semiconductor chip to electrically connect the wiring board and semiconductor chip to each other; an insulating resin layer formed between the wiring board and the semiconductor chip to surround the internal connection terminals; a reinforcing member provided at least on a semiconductor chip mounting surface of the wiring board; and supporting plate provided on the reinforcing member.

According to another aspect of the present invention, there is provided a semiconductor device manufacturing method comprising dividing a wafer on which semiconductor elements have been formed into individual semiconductor chips; respectively forming reinforcing members containing heat-meltable resin as a main component on rear surfaces of the semiconductor chips opposite to circuit forming surfaces thereof; picking up the semiconductor chip together with a corresponding one of the reinforcing members; mounting the picked-up semiconductor chip on the wiring board in a flip chip interconnection fashion; and applying high pressure to the reinforcing member formed on the rear surface of the semiconductor chip at high temperatures to drive out the reinforcing member to an outer portion of the semiconductor chip.

### BRIEF DESCRIPTION OF THE SEVERAL VIEWS OF THE DRAWING

FIGS. 1A to 1E are schematic views sequentially showing the manufacturing steps for illustrating a conventional semiconductor device and a manufacturing method thereof;

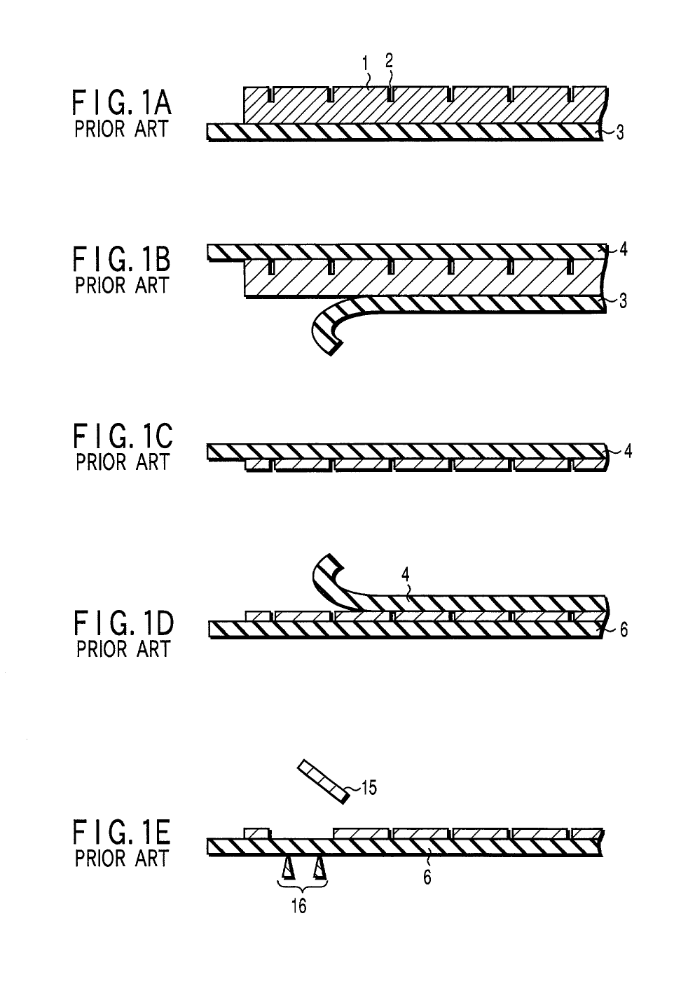

FIGS. 2A to 2G are schematic views sequentially showing steps from a dicing groove forming step to a pickup step for illustrating a semiconductor device and a manufacturing method thereof according to a first embodiment of this invention;

FIGS. 3A to 3D are schematic views sequentially showing steps from an ACP coating step to a package takeout step for illustrating the semiconductor device and the manufacturing method thereof according to the first embodiment of this invention;

FIGS. 4A to 4C are schematic views sequentially showing manufacturing steps for illustrating a semiconductor device and a manufacturing method thereof according to a second embodiment of this invention;

FIGS. 5A to 5D are schematic views sequentially showing manufacturing steps for illustrating a semiconductor device and a manufacturing method thereof according to a third embodiment of this invention;

FIGS. 6A to 6D are schematic views sequentially showing manufacturing steps for illustrating a semiconductor device and a manufacturing method thereof according to a fourth embodiment of this invention; and

FIGS. 7A to 7D are schematic views sequentially showing manufacturing steps for illustrating a semiconductor device and a manufacturing method thereof according to a fifth embodiment of this invention.

### DETAILED DESCRIPTION OF THE INVENTION

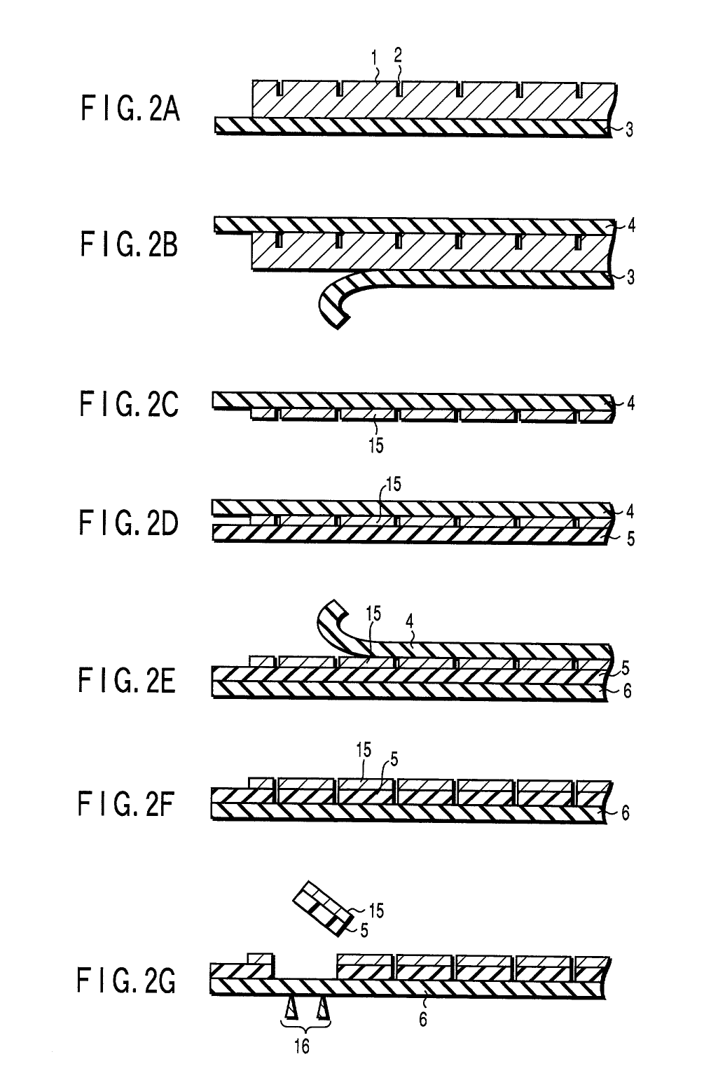

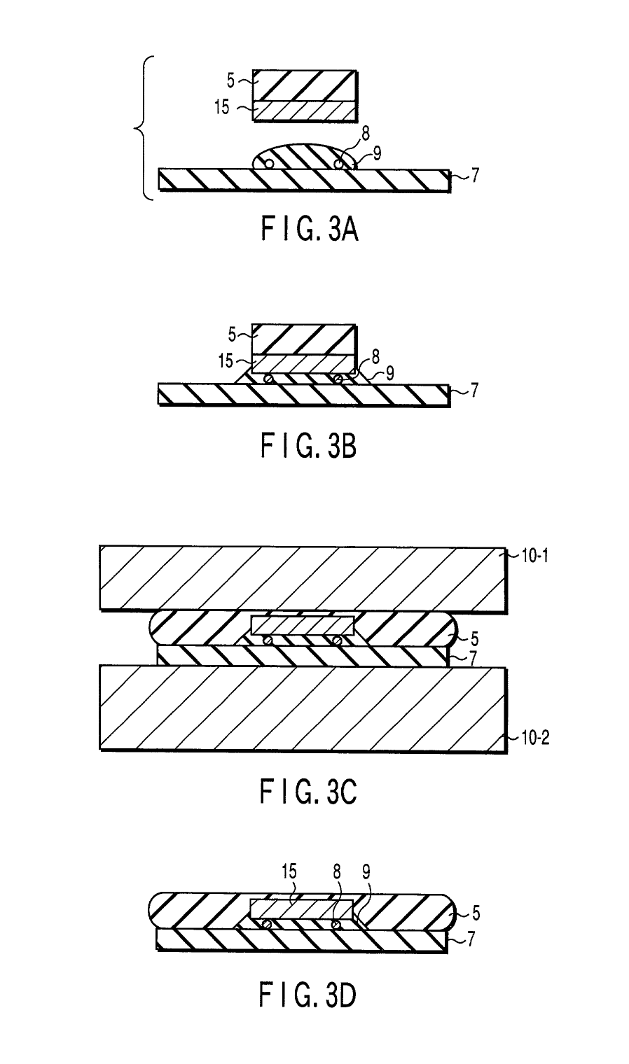

FIGS. 2A to 2G and FIGS. 3A to 3D are schematic views sequentially showing respective steps for illustrating a semiconductor device and a manufacturing method thereof according to a first embodiment of this invention. FIG. 2A shows a dicing groove forming step, FIG. 2B shows a holding tape re-affixing step, FIG. 2C shows a BSG step, FIG. 2D shows a reinforcing member adhering step, FIG. 2E shows a holding tape re-affixing step, FIG. 2F shows a reinforcing member cutting step, and FIG. 2G shows a pickup step. Further, FIG. 3A shows an ACP coating step, FIG. 3B shows an ACP connecting step, FIG. 3C shows a reinforcing member rolling step, and FIG. 3D shows a package takeout step.

First, a process from the dicing groove forming step to the pickup step is explained with reference to FIGS. 2A to 2G. After a holding tape 3 is affixed to the rear surface opposite to a circuit forming surface of a wafer 1 on which semiconductor elements have been formed, a dicing groove 2 is formed according to the external forms of semiconductor chips (FIG. 2A). The dicing groove 2 is formed to have a depth less than the thickness of the wafer 1 and larger than the thickness of a finally obtained semiconductor chip. Next, the holding tape 3 on the wafer 1 is removed from the rear surface of the wafer 1 opposite to the circuit forming surface thereof and a holding tape 4 is affixed to the circuit forming surface (FIG. 2B) and then the rear surface of the wafer is ground by use of the BSG technique (FIG. 2C). In this case, it is possible to use a method, such as chemical etching, instead of the BSG technique. At this time, a semiconductor chip 15, whose thickness is reduced and which is separated by the rear surface grinding process, is exposed at the rear surface. To the rear surface of the chip 15, a reinforcing member (reinforcing resin) 5 containing thermoplastic resin is adhered (FIG. 2D). In the first embodiment, the reinforcing member 5 is supplied in a sheet form and adhered to the rear surface of the semiconductor chips 15 by hot-pressing. After this, the holding tape 4 is removed from the semiconductor circuit forming surface and a holding tape 6 is affixed to the rear surface of the reinforcing member 5 (FIG. 2E), then a dicing process is effected again to cut apart the reinforcing member 5 (FIG. 2F). After cutting apart the reinforcing member 5, the semiconductor chip 15 is picked up together with the reinforcing member 5 from the holding tape 6 by use of pickup needles 16 (FIG. 2G).

With the technique disclosed in Jpn. Pat. Appln. KOKAI Publication No. H11-40520 described above, there is a possibility that cracks will occur in the semiconductor chip 15 in the step of picking up the semiconductor chip 15 if the thickness thereof is further reduced, but in the present embodiment, since the semiconductor chip is picked up together with the reinforcing member 5, the probability that cracks will occur in the semiconductor chip 15 can be significantly suppressed. Further, the degree of warping occurring in the semiconductor chip 15 can be significantly lowered by maintaining the balance between the contraction stress of an insulating film or the like on the circuit forming surface and the contraction stress of the reinforcing member 5 on the rear surface. Alternatively, a warp may be caused in a convex form on the circuit forming surface which is mechanically stronger by setting the contraction stress of the reinforcing member 5 on the rear surface larger than the contraction stress on the circuit forming surface. This is extremely effective in a case where the element forming surface of the semiconductor chip 15 is covered with a high polymeric organic film such as polyimide.

Since the semiconductor chip 15 obtained by the above method has an extremely strong structure, the semiconductor chip 15 will not be broken in the later transfer process. Further, since the reinforcing member 5 is formed of thermoplastic resin, the thickness of a final product can be made thin, as in the conventional, case by hot-pressing the semiconductor chip as required.

Next, a process from the ACP coating step to the package takeout step is explained with reference to FIGS. 3A to 3D. In the first embodiment, a method for hot-pressing the reinforcing member 5 at the time of connection to a package board (wiring board or substrate) is used. That is, anisotropic conductive paste (ACP) 9 is coated on a semiconductor chip mounting region of a package board 7 having bumps (internal connection terminals) 8 formed in portions for connection with the semiconductor chip 15, the circuit forming surface of the semiconductor chip 15 with the reinforcing member 5 is placed to face the package board (FIG. 3A), and the semiconductor chip is mounted on the package board 7 in a flip chip interconnection method (FIG. 3B). After this, by effecting the hot-pressing process by use of reinforcing resin rolling molds 10-1, 10-2, anisotropic conductive paste 9 is cured to complete connection between the semiconductor chip 15 and the package board 7, and at the same time, the reinforcing member 5 on the rear surface of the chip is softened to spread over to an area outside the semiconductor chip 15 (FIG. 3C). At this time, if the surface portion of a pressure tool (reinforcing resin rolling mold 10-1) which is brought into contact with the reinforcing member 5 is formed of an inactive material such as Teflon (registered trademark by U.S. DuPont Co., tetrafluoroethylene polymer), for example, a structure in which the thermoplastic resin (reinforcing member) 5 on the rear surface of the semiconductor chip 15 is made extremely thin and the package board 7 lying near the outer periphery of the semiconductor chip 15 is reinforced with the thermoplastic resin 5 can be attained when the pressure tool 10-1 is cooled and the semiconductor chip 15 is taken out (FIG. 3D). After this, an unwanted portion of the outer periphery of the thermoplastic resin 5 is cut apart and removed to complete a package.

In the thus completed semiconductor device, the thickness of the package board 7 is 50 μm, the diameter of the bump 8 is 30 to 40 μm and the thickness of the reinforcing member (remaining thermoplastic resin) 5 on the rear surface of the semiconductor chip 15 is 50 μm, or preferably, 10 to 20 μm if the thickness of the semiconductor chip 15 is 50 μm, for example.

With the above structure and manufacturing method, since the reinforcing member (reinforcing resin layer) is formed on the rear surface of the semiconductor chip 15 opposite to the circuit forming surface thereof, the semiconductor chip 15 is not warped or a warp may be caused in a convex form on the circuit forming surface which is mechanically stronger even when the semiconductor chip 15 is made thin. Therefore, the occurrence of cracks of the semiconductor chip 15 due to formation of the warp can be suppressed.

Further, since the rear surface of the semiconductor chip 15 is reinforced with the reinforcing member 5, breakage of the semiconductor chip 15 in the steps after the semiconductor chip 15 is separated, that is, in the pickup step from the holding tape 6, in the transfer process between the steps or in the step, in the test step or the like can be suppressed.

Further, since the reinforcing member 5 on the rear surface of the semiconductor chip is softened and collapsed by placing the semiconductor chip under high pressure at high temperatures, the thickness of a final product can be reduced to the same degree as that attained when the reinforcing member 5 is not formed.

Thus, it is possible to attain a semiconductor device and a manufacturing method thereof in which the occurrence of the warp of the semiconductor chip whose thickness is reduced can be suppressed and which has a sufficiently high strength to withstand the damage occurring in the later steps.

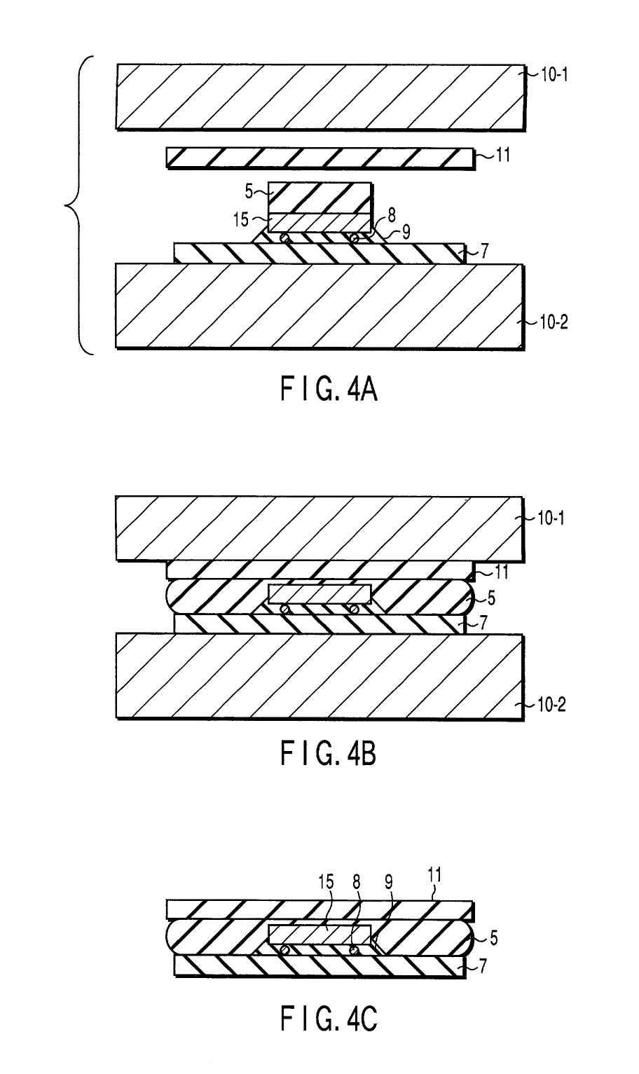

FIGS. 4A to 4C are schematic views showing steps for illustrating a semiconductor device and a manufacturing method thereof according to a second embodiment of this invention and showing a modification of the first embodiment. FIG. 4A shows a step of placing a supporting plate and a semiconductor device to which ACP connection is made into a mold, FIG. 4B shows a step of rolling reinforcing member adhered to the rear surface of a semiconductor chip and FIG. 4C shows a package takeout step.

In the second embodiment, after the semiconductor chip 15 with the reinforcing member 5 and the package board 7 are placed to face each other with an anisotropic conductive paste 9 disposed therebetween, a supporting plate 11 formed of a material having a sufficiently high softening point (which is not melted at a temperature equal or lower than 100° C.) is placed on the reinforcing member 5 (FIG. 4A) and a hotpressing process is effected by use of reinforcing resin rolling molds 10-1, 10-2 (FIG. 4B). As the material of the supporting plate 11, it is preferable to use metal, ceramic, glass, glass epoxy, or engineering plastic. Of course, a combination of the above materials can be used. By use of the above method, a package with the cover plate (supporting plate) 11 can be obtained (FIG. 4C).

A package board can be used as the supporting plate 11. Further, if a package board is used as the supporting plate 11 and a semiconductor chip with the reinforcing member is stacked on the package board with an anisotropic conductive paste disposed therebetween, two semiconductor chips can be mounted in a stacked form. Likewise, three or more semiconductor chips can be mounted in a stacked form.

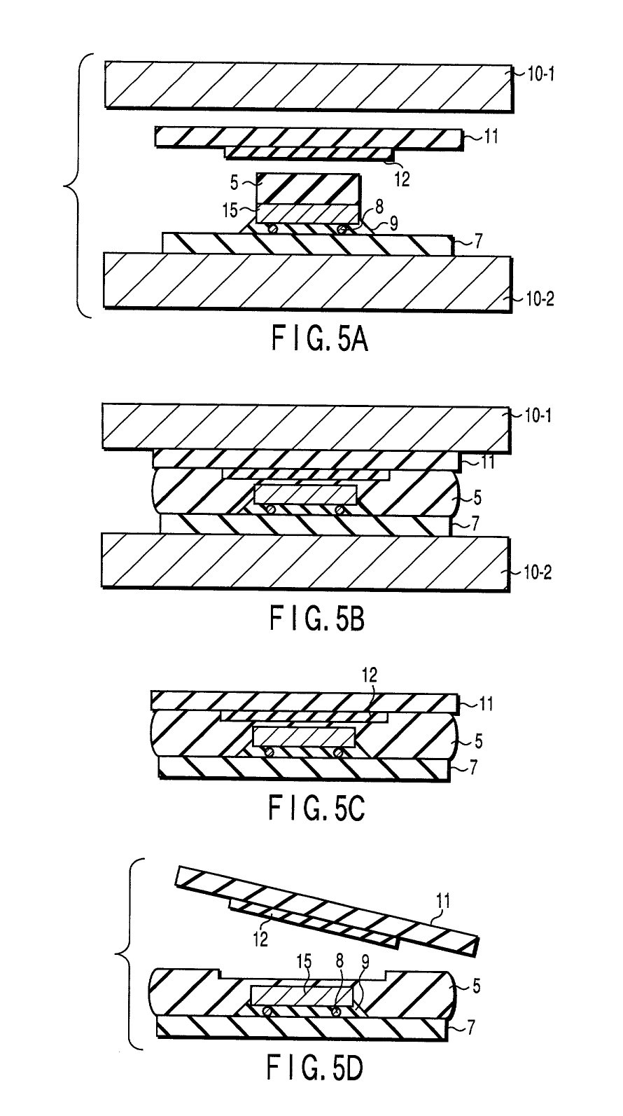

FIGS. 5A to 5D are views schematically showing steps for illustrating a semiconductor device and a manufacturing method thereof according to a third embodiment of this invention and showing an example developed from the first and second embodiments. FIG. 5A shows a step of placing a supporting plate and a semiconductor device to which ACP connection is made into a mold, FIG. 5B shows a step of rolling reinforcing member adhered to the rear surface of a semiconductor chip, FIG. 5C shows a package takeout step and FIG. 5D shows a step of removing a cover plate (supporting plate) 11.

In the third embodiment, an inactive film (weak-adhesion region) 12 equal in size to or larger than the semiconductor chip 15 is provided on the central portion of the supporting plate 11. After the semiconductor chip 15 with the reinforcing member 5 and the package board 7 are placed to face each other with anisotropic conductive paste 9 disposed therebetween, the supporting plate 11 is placed on the reinforcing member 5 on the rear surface so that the inactive film 12 on the central portion will face the semiconductor chip 15 (FIG. 5A) and a hot-pressing process is effected by use of reinforcing resin rolling molds 10-1, 10-2 (FIG. 5B).

Since the cover plate 11 is not adhered to the semiconductor chip 15 in the package shown in FIG. 5C and obtained by use of the above method, it is possible to easily remove the cover plate 11 without damaging the semiconductor chip 15 as shown in FIG. 5D. In addition, a rigid structure which is more resistant against breakage in the steps after packaging, that is, in the product test step, in the step of transfer to the secondary mounting location or in the secondary mounting step in comparison with the first embodiment can be provided, and a mounting product which is thinner than in the case of the second embodiment can be provided.

As the inactive film 12, Teflon or gold can be most effectively used, but another material, for example platinum, silicone resin and nickel can be used if the adhesion thereof with thermoplastic resin of the reinforcing member 5 is low. Further, a fragile thin film (weak-adhesion layer) can be formed instead of the inactive film 12. As the fragile thin film, a surface active agent in a liquid form may be coated or an oxide film may be formed if the supporting plate 11 is formed of copper.

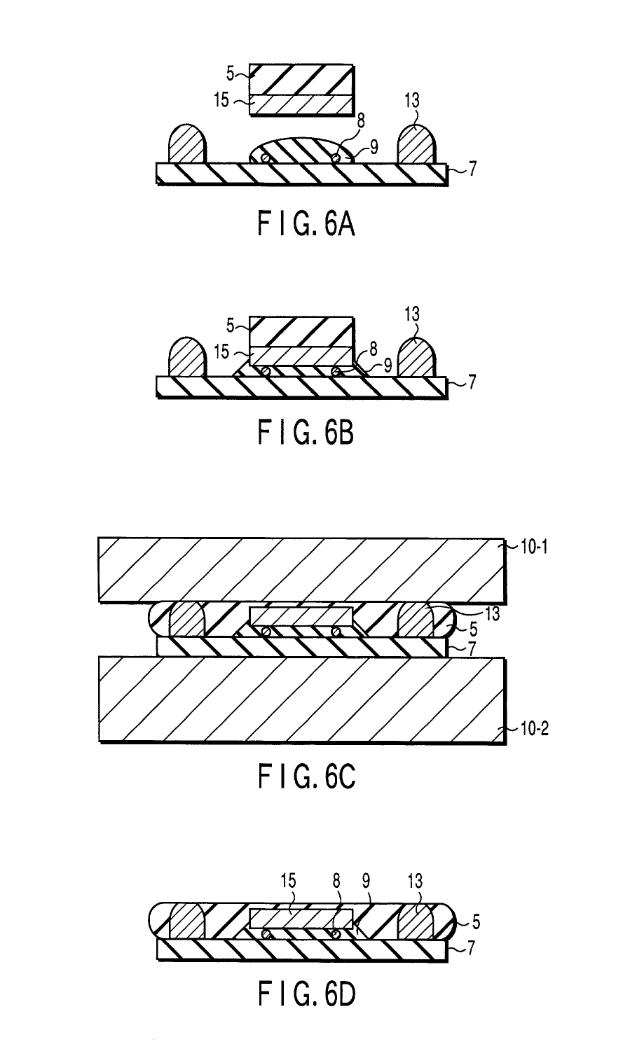

FIGS. 6A to 6D are views schematically showing steps for illustrating a semiconductor device and a manufacturing method thereof according to a fourth embodiment of this invention and showing a modification of each of the above embodiments. FIG. 6A shows an ACP coating step, FIG. 6B shows an ACP connection step, FIG. 6C shows a reinforcing resin rolling step and FIG. 6D shows a takeout step from a mold.

Bumps 8 are formed on internal connection portions of a package board 7 which are formed for connection with a semiconductor chip 15 and external connection terminals 13 are formed on the same surface as the forming surface of the bumps 8 and outside a semiconductor chip mounting region of the package board 7. The package board 7 and the semiconductor chip 15 with a reinforcing member 5 are placed to face each other with anisotropic conductive paste 9 disposed therebetween (FIG. 6A), then the semiconductor chip 15 is mounted on the package board 7 by use of the anisotropic conductive paste 9 (FIG. 6B) and a hot-pressing process is effected by use of reinforcing resin rolling molds 10-1, 10-2 (FIG. 6C). The reinforcing member 5 formed of thermoplastic resin on the rear surface of the semiconductor chip 15 is softened to spread over to an area outside the semiconductor chip 15 and surround the external connection terminals 13.

The package obtained by the above method has a structure in which the external connection terminals 13 are arranged outside the semiconductor chip 15 as shown in FIG. 6D and can be secondarily mounted in a simple manner by a hot-pressing process. Further, another package board can be mounted on the above package and may be electrically connected to the external connection terminals 13. In addition, a plurality of semiconductor devices (packages) formed by the above method can be mounted in a stacked form.

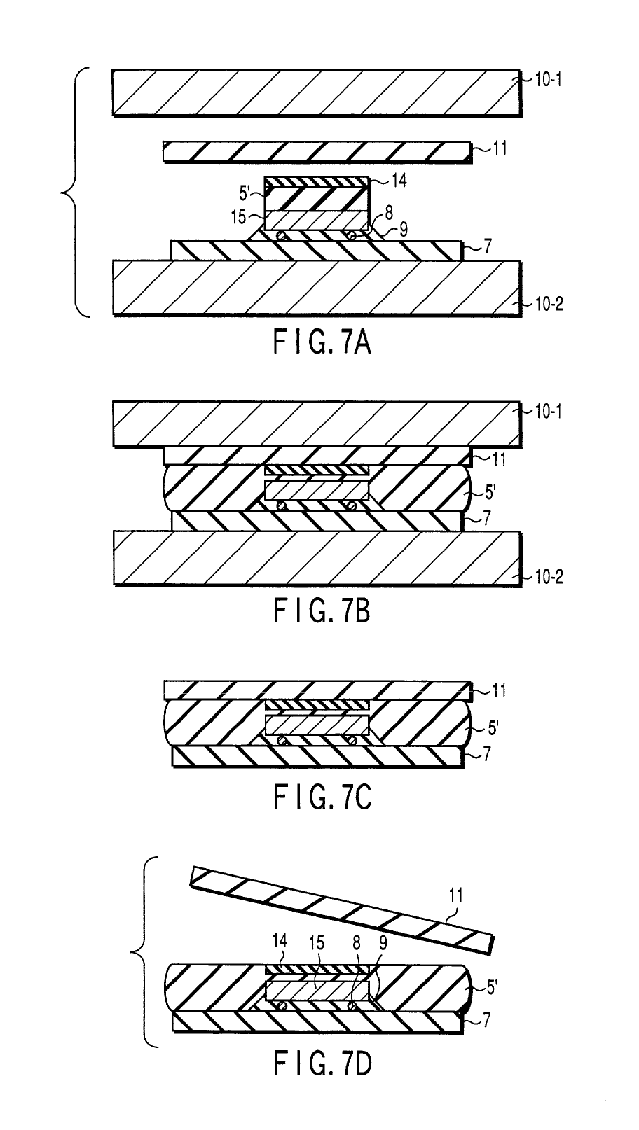

FIGS. 7A to 7D are views schematically showing steps for illustrating a semiconductor device and a manufacturing method thereof according to a fifth embodiment of this invention and showing an example developed from the third embodiment. FIG. 7A shows a step of setting a supporting plate and a semiconductor device to which ACP connection is made into a mold, FIG. 7B shows a step of rolling a reinforcing member adhered to the rear surface of a semiconductor chip, FIG. 7C shows a step of taking out the device from the mold, and FIG. 7D shows a supporting plate removing step.

In the fifth embodiment, a structure obtained by adhering a first supporting plate 14 formed of a material having a sufficiently high softening point (which is not melted at a temperature equal or lower than 100° C.) by use of an adhesive agent (adhesive resin layer) 5′ containing thermoplastic resin is used as a reinforcing member on the rear surface of the semiconductor chip 15. After the semiconductor chip 15 with the above structure and a package board 7 are placed to face each other with an anisotropic conductive paste 9 disposed therebetween, a second supporting plate 11 is placed on the first supporting plate 14 (FIG. 7A) and a hot-pressing process is effected by use of reinforcing resin rolling molds 10-1, 10-2 (FIG. 7B). As a result, the adhesive agent 5′ containing thermoplastic resin is softened to spread over to an area outside the semiconductor chip 15.

By use of the above method, since the second supporting plate 11 is completely separated from the rear surface of the semiconductor chip 15 as shown in FIG. 7C, damage given to the semiconductor chip 15 when the second supporting plate 11 shown in FIG. 7D is removed can be more suppressed than in the case of the third embodiment.

It is of course possible to hot-press a semiconductor chip 15 to which a first supporting plate 14 formed of a material having a sufficiently high softening point is adhered with an adhesive agent (adhesive resin layer) 5′ containing thermoplastic resin by use of reinforcing resin rolling molds 10-1, 10-2 without using the second supporting plate 11 and soften the adhesive agent 5′ to spread over to an area outside the semiconductor chip 15.

In each of the above embodiments, the wafer is diced and divided after the reinforcing member (thermoplastic resin) 5 affixed to the rear surface of the semiconductor chip 15 is simultaneously adhered to the whole portion of the wafer, but it is also possible to omit the dicing process by respectively affixing individually divided reinforcing members (thermoplastic resin) to discrete semiconductor chips 15. Further, as the reinforcing member 5 adhered to the rear surface of the semiconductor chip 15, thermosetting resin formed in a B stage form can be used instead of thermoplastic resin. In each of the above embodiments, connection to the package board 7 is made by use of the anisotropic conductive paste 9, but it is also possible to use metal fusion connection by use of solder bumps or metal stud bumps.

According to the semiconductor device and the manufacturing method thereof according to each of the above embodiments of the present invention, the following effects (1) to (3) can be obtained.

(1) Since no warp occurs in the semiconductor chip even if it is made thin or a convex warp occurs in a convex form on the circuit forming surface which is mechanically strong, the occurrence of cracks in the semiconductor chip due to the warp can be suppressed.

(2) Since the rear surface of the semiconductor chip is reinforced, breakage of the semiconductor chip in the steps after separation, that is, in the pickup step from the holding tape, in the transfer process between the steps or in the step, in the test step or the like can be suppressed.

(3) Since the reinforcing member on the rear surface of the semiconductor chip is softened and collapsed by the application of a high pressure at high temperatures, the thickness of a final product can be made thin irrespective of whether the reinforcing member is present or not.

Further, since the reinforcing member on the rear surface of the semiconductor chip can be reversibly melted/cured if a material containing thermoplastic resin as a main component is used as the reinforcing member, the film thickness reducing step by the application of a high pressure at high temperatures can be effected after another high-temperature process.

Since the reinforcing effect of the semiconductor chip can be more securely attained by using the supporting plate, the probability of breakage can be further suppressed.

Further, if the supporting plate is removed in a semiconductor device mounting location, the semiconductor device with the reinforced structure can be transferred to the mounting location and the probability of breakage can be further suppressed. After the supporting plate is removed, a thin package can be obtained.

If the reinforcing member and the supporting plate are placed to face each other while a material layer (first supporting plate) which is not melted at a temperature equal or lower than 100° C. is disposed therebetween on the semiconductor chip mounting region and they are made in direct contact with each other in an area outside the semiconductor chip, damage to the semiconductor device can be suppressed to minimum and the probability of breakage can be further suppressed when the supporting plate (second supporting plate) is removed in the mounting location of the semiconductor device.

The semiconductor devices according to the second and fourth embodiments can be mounted in a stacked form.

As described above, according to one aspect of the present invention, it is possible to provide a semiconductor device in which the occurrence of a warp on the thinned semiconductor chip can be suppressed and which is strong enough to withstand the damage occurring in the later steps, and a manufacturing method of the same.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A semiconductor device comprising:
a wiring board;
a semiconductor chip arranged with a circuit forming surface thereof facing said wiring board;
internal connection terminals disposed between said wiring board and said semiconductor chip to electrically connect said wiring board and semiconductor chip to each other;
an insulating resin layer formed between said wiring board and said semiconductor chip to surround said internal connection terminals;
a reinforcing member provided at least on a semiconductor chip mounting surface of said wiring board; and
a supporting plate provided on said reinforcing member.

2. The semiconductor device according to claim 1, wherein said reinforcing member contains thermoplastic resin as a main component.

3. The semiconductor device according to claim 1, wherein said reinforcing member is formed to extend on a rear surface of said semiconductor chip opposite to the circuit forming surface thereof and the thickness of said reinforcing member between the rear surface of said semiconductor chip and said supporting plate is not larger than 50 μm.

4. The semiconductor device according to claim 1, wherein said supporting plate is formed of a material which is not melted at a temperature not higher than 110° C.

5. The semiconductor device according to claim 1, wherein said supporting plate is a material containing at least one selected from a group consisting of metal, ceramic, glass, glass epoxy, thermosetting resin, engineering plastic and a combination thereof.

6. The semiconductor device according to claim 1, in which said reinforcing member is formed to extend on a rear surface of said semiconductor chip opposite to the circuit forming surface thereof and which further comprises an inactive film provided on a surface of said supporting plate which faces said reinforcing member and corresponds to at least an area in which said semiconductor chip is arranged.

7. The semiconductor device according to claim 6, wherein said inactive film is a material containing at least one selected from a group consisting of tetrafluoroethylene polymer, silicone resin, gold, platinum and nickel.

8. The semiconductor device according to claim 1, in which said reinforcing member is formed to extend on a rear surface of said semiconductor chip opposite to the circuit forming surface thereof and which further comprises a weak-adhesion layer provided on a surface of said supporting plate which faces said reinforcing member and corresponds to at least an area in which said semiconductor chip is arranged.

9. The semiconductor device according to claim 8, wherein said weak-adhesion layer is a coating layer of a surface active agent in a liquid form.

10. The semiconductor device according to claim 8, wherein said supporting plate is formed of copper and the weak-adhesion layer is a copper oxide film.

11. The semiconductor device according to claim 1, wherein said reinforcing member and supporting plate are set in contact with each other while a material layer which is not melted at a temperature not higher than 100° C. is disposed therebetween on a semiconductor chip mounting region and said reinforcing member and supporting plate are made in direct contact with each other in an area outside the semiconductor chip.

12. The semiconductor device according to claim 1, wherein said supporting plate is removable.

13. The semiconductor device according to claim 1, further comprising external connection terminals connected to a portion outside a semiconductor chip mounting region on the semiconductor chip mounting surface of said wiring board, said external connection terminals being surrounded by said reinforcing member.

14. The semiconductor device according to claim 13, wherein said supporting plate is a wiring board different from said wiring board on which said semiconductor chip is mounted and electrically connected to said external connection terminals.

15. A semiconductor device manufacturing method comprising:
dividing a wafer on which semiconductor elements have been formed into individual semiconductor chips;
respectively forming reinforcing members, containing heat-meltable resin as a main component, on rear surfaces of the semiconductor chips opposite to circuit forming surfaces thereof;
picking up the semiconductor chip together with a corresponding one of the reinforcing members;
mounting the picked-up semiconductor chip on a wiring board in a flip chip interconnection fashion; and
applying a high pressure to the reinforcing member formed on the rear surface of the semiconductor chip at high temperatures to drive out the reinforcing member to an outside portion of the semiconductor chip.

16. The semiconductor device manufacturing method according to claim 15, wherein the dividing of the wafer includes forming a groove which is deeper than the thickness of a semiconductor chip at the time of completion, along dicing lines of the wafer on which the semiconductor elements have been formed, on the circuit forming surface side of the wafer; affixing a holding member on the circuit forming surface of the wafer; and grinding the rear surface of the wafer opposite to the circuit forming surface thereof to the thickness of the semiconductor chip at the time of completion, to divide the wafer into individual semiconductor chips.

17. The semiconductor device manufacturing method according to claim 15, wherein the reinforcing member is melted and flows out to the outside portion of the semiconductor chip and the flowed-out resin forms a reinforcing resin layer on the wiring board upon applying a high pressure to the reinforcing member formed on the rear surface of the semiconductor chip at high temperatures to drive out the reinforcing member to the outside portion of the semiconductor chip.

18. The semiconductor device manufacturing method according to claim 15, wherein the forming of the reinforcing members includes adhering a supporting plate which is not melted at a temperature not higher than 100° C. to the rear surface of the semiconductor chip while an adhesive resin layer containing heat-meltable resin as a main component is disposed therebetween, and the applying of a high pressure to the reinforcing member includes melting the adhesive resin layer to drive out the adhesive resin layer to the outside portion of the semiconductor chip by applying a high pressure to the supporting plate at high temperatures.

19. The semiconductor device manufacturing method according to claim 15, wherein the applying of a high pressure to the reinforcing member includes placing a supporting plate which is not melted at a temperature not higher than 100° C. on the reinforcing member adhered to the rear surface of the semiconductor chip, melting the reinforcing member to drive out the reinforcing member to the outside portion of the semiconductor chip by applying a high pressure to the supporting plate at high temperatures, and fixing the wiring board and the supporting plate to each other by use of the flowed-out resin.

20. The semiconductor device manufacturing method according to claim 15, wherein the forming of the reinforcing members includes adhering a first supporting plate which is not melted at a temperature not higher than 100° C. to the rear surface of the semiconductor chip while an adhesive resin layer containing heat-meltable resin as a main component is disposed therebetween, and the applying of a high pressure to the reinforcing member includes placing a second supporting plate which is not melted at a temperature not higher than 100° C. on the first supporting plate adhered to the rear surface of the semiconductor chip and melting the adhesive resin layer to drive out the adhesive resin layer to the outside portion of the semiconductor chip by applying a high pressure to the second supporting plate at high temperatures.

21. The semiconductor device manufacturing method according to claim 19, wherein the supporting plate is removed in the case where the semiconductor device is mounted.

22. The semiconductor device manufacturing method according to claim 20, wherein the second supporting plate is removed in the case where the semiconductor device is mounted.
